(19) United States
(12) Patent Application Publication
(10) Pub. No.: US 2023/0122033 A1
(43) Pub. Date: Apr. 20, 2023

(54) Metering Data Collection Unit with Battery Energy Calculator, and Ultrasonic Meter and Remote Data Collection System Having the Same

(71) Applicant: IS TECHNOLOGIES CO., LTD., Incheon (KR)

(72) Inventor: Gab Sang Yoo, Incheon (KR)

(21) Appl. No.: 17/501,205

(22) Filed: Oct. 14, 2021

(51) Int. Cl. H04L 29/08; H04W 4/70; G01R 22/06

(52) U.S. Cl. CPC H04L 67/12; H04W 4/70; G01R 22/061

(57) ABSTRACT

Disclosed is remote meter-reading technology that can be used for remote meter-reading of gas, electricity, tap water, etc. Technology and an apparatus or system capable effectively measuring a battery level with low power consumption is provided. A remote meter-reading terminal unit calculates the level of a battery while obtaining power consumption in an operation mode of an MCU using current output from the battery and obtaining power consumption in a sleep mode using a predetermined current value.

### BACKGROUND OF THE INVENTION

### Field of the Invention

The present invention relates to remote meter-reading technology that can be used for remote meter-reading of gas, electricity, tap water, etc.

### Discussion of the Related Art

In measuring the use amount of gas, electricity, tap water, etc., a meter reader directly checked the same with. the naked eve and recorded the same in the past. In recent years, however, switchover to remote meter-reading has been rapidly performed due to development of communication and sensor technology and an increase in personnel expenses.

A remote meter-reading terminal unit receives metering information from a meter and transmits the same to an external server or another terminal unit (e.g. a concentrator) through a communication module.

In general, the remote meter-reading terminal unit has a battery built therein. Battery power consumption is greatly increased when the remote meter-reading terminal unit receives metering information from the meter or transmits the information to the outside, and the remote meter-reading terminal unit enters a sleep mode during other times in order to minimize battery power consumption.

Also, in order to minimize data loss, a battery level is checked, and the remote meter-reading terminal unit is set to selectively perform necessary operation depending on the battery level. For example, a normal mode or a power-saving mode may be executed depending on the battery level, and only minimum operations are performed in the power-saving mode.

Conventionally, power consumption is measured using a battery management system (BMS) IC device in order to measure the battery level. In this case, there is a problem with an increase in cost by the provision of the IC device.

Alternatively, current consumption may be measured using a resistance element. In this case, however, power consumption is increased at the time of measurement of current consumption.

Therefore, technology capable of accurately measuring the battery level with low power consumption is needed.

### SUMMARY OF THE INVENTION

Accordingly, the present invention is directed to a remote meter-reading terminal unit having a battery level detection function and an ultrasonic meter and a remote meter-reading system including the same that substantially obviate one or more problems due to limitations and disadvantages of the related art.

It is an object of the present invention to provide technology and an apparatus or system capable of effectively measuring a battery level with low power consumption.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a remote meter-reading terminal unit periodically receives flow-rate information from a metering unit and transmits the flow-rate information to the outside through a communication network, wherein the remote meter-reading terminal unit includes a memory configured to store the flow-rate information, a communication module configured to perform data transmission to the outside, and a microcomputer unit (MCU) having an operation mode in which at least one processor is operated and a sleep mode in which all processors are dormant, the MCU including a battery level processor configured to calculate the level of the battery, the battery level processor using current output from the battery to obtain power consumption in the operation mode and using a predetermined current value to obtain power consumption in the sleep mode.

The battery current output may be converted by an analog-to-digital converter (ADC) in the MCU before being used to obtain the power consumption in the operation mode.

The predetermined current value may include a current value stored in the memory.

The MCU may further include a flow-rate reception processor configured to receive the flow-rate information from the metering unit in a first cycle and to store the flow-rate information in the memory and an outward transmission processor configured to transmit the flow-rate information to the outside in a second cycle greater than the first cycle, and the battery level processor may be operated during operation of the flow-rate reception processor or the outward transmission processor.

The first cycle may be 1 hour while the second cycle may be 24 hours, and the outward transmission processor may transmit all flow-rate information received after outward transmission during the previous cycle.

The remote meter-reading terminal unit may further include a current measurement circuit configured to measure the current output from the battery, wherein the current measurement circuit may include a resistor connected to a positive terminal and a negative terminal of the battery therebetween, a first current distributer having a positive side connected to a positive side of the resistor and a negative side connected to an input side of the MCU, and a second current distributer having a negative side connected to a negative side of the resistor and a positive side connected to the negative side of the first current distributer.

In another aspect, an ultrasonic meter includes the remote meter-reading terminal unit.

In a further aspect, a remote meter-reading system includes an ultrasonic metering unit installed in a flow-rate measurement target pipe, the remote meter-reading terminal unit, and a server configured to receive flow-rate information from the remote meter-reading terminal unit through an external communication network.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 shows a remote meter-reading system according to an embodiment of the present invention;

FIG. 2 shows the construction of a current measurement circuit of a remote meter-reading terminal unit according to an embodiment of the present invention;

FIG. 3 schematically shows a metering information reception cycle according to an embodiment of the present invention; and

FIG. 4 shows current values of an MCU in an operation mode and a sleep mode according to an embodiment of the present invention.

### DETAILED DESCRIPTION OF THE INVENTION

Hereinafter, embodiments of the present invention will be described in detail with reference to the accompanying drawings. In the following description of the present invention, a detailed description of known functions and configurations incorporated herein will be omitted when it may make the subject matter of the present invention rather unclear.

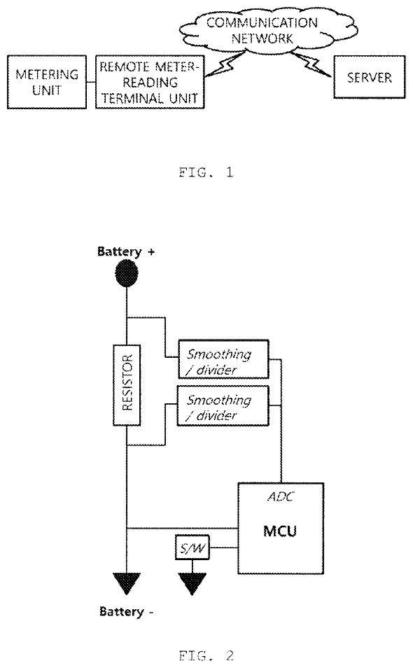

First, a remote meter-reading system according to an embodiment of the present invention will be described with reference to FIG. 1.

The remote meter-reading system includes a metering unit, a remote meter-reading terminal unit, and a server.

The metering unit measures the use amount of a measurement target and transmits the same to the remote meter-reading terminal unit.

Here, the measurement target may be at least one of gas, tap water, electricity, and hot water.

When the measurement target is tap water, the metering unit may be an ultrasonic meter, which is conventionally well known.

The metering unit and the remote meter-reading terminal unit may be connected to each other by wire. Alternatively, the metering unit and the remote meter-reading terminal unit may be only communicatively connected to each other through wireless communication in a state of being physically separated from each other.

Illustratively, the remote meter-reading terminal unit and the metering unit may be integrated to constitute an ultrasonic meter.

Alternatively, a meter including the metering unit may be installed in a water pipe, and the remote meter-reading terminal unit may be electrically connected to the meter by wire in order to receive information while being spaced apart from the meter.

In addition, the remote meter-reading terminal unit is communicatively connected to the server through a wired or wireless communication network.

Illustratively, the server may be a server operated by an organization that charges consumers for consumption. For example, the server may be a server operated by a self-governing body for charging.

FIG. 2 is a conceptual view of a current measurement circuit included in the remote meter-reading terminal unit.

As shown in FIG. 2, the current measurement circuit may be provided between a positive side and a negative side of a battery in order to measure current output from the battery and to input the same to an MCU.

Specifically, the current measurement circuit includes a resistor connected to a positive terminal and a negative terminal of the battery therebetween, a first current distributer having a positive side connected to a positive side of the resistor and a negative side connected to an input side of the MCU, and a second current distributer having a negative side connected to a negative side of the resistor and a positive side connected to the negative side of the first current distributer.

The MCU has an ADC built therein, and the ADC converts current input thereto into a digital signal.

The MCU has an operation mode in which at least one built-in processor is operated and a sleep mode in which all processors are dormant.

The processors built in the MCU include a flow-rate reception processor, an outward transmission processor, and a battery level processor.

The flow-rate reception processor receives flow-rate information from the metering unit in a first cycle and stores the same in a memory.

The outward transmission processor transmits the flow-rate information stored in the memory to the outside in a second cycle.

The battery level processor operated during operation of the flow-rate reception processor or the outward transmission processor.

Preferably, the outward transmission processor is operated when the flow-rate reception processor is operated. That is, the length of the second cycle is an integer multiple of the length of the first cycle.

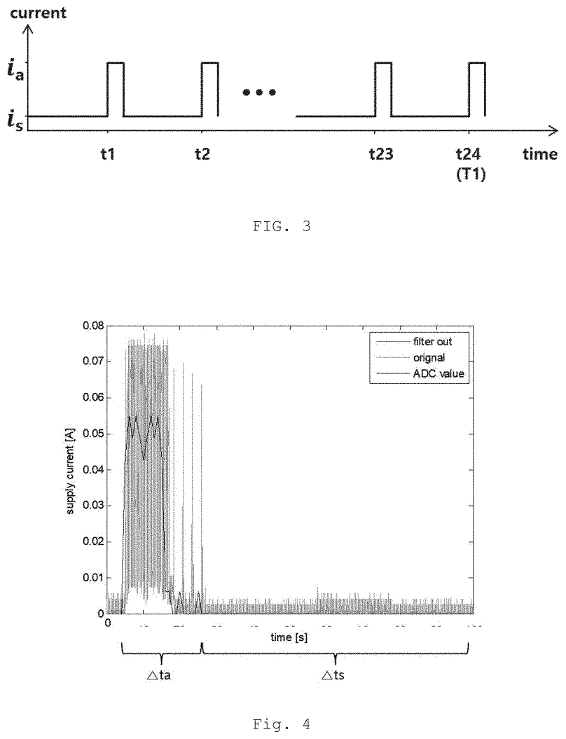

FIG. 3 schematically shows current values of the MCU in the operation mode and the sleep mode.

in FIG. 3, the first cycle is 1 hour, and the second cycle is 24 hours. That is, metering information is received from the metering unit and is stored in the memory at one-hour intervals, and the information is transmitted to the server through a communication module once a day.

Referring to FIG. 3, battery power is maximally consumed (output current: ia) when the processor is operated, whereas battery power is minimally consumed (output current: is) in the sleep mode.

The battery level processor obtains battery power consumption in the operation mode using current output from the battery and obtains battery power consumption in the sleep mode using a predetermined current value. Here, the sleep mode is set to be temporally longer than the operation mode.

In the sleep mode, only minimum current flows, whereby battery power consumption is minimized.

Battery power consumption in the operation mode is calculated when the flow-rate reception processor is operated, and therefore separate power consumption necessary to calculate battery power consumption is also minimized.

Battery current in the operation mode may be measured as current input to the MCU through the above-described measurement circuit. Preferably, a current value using an ADC value converted by the ADC in the MCU is used to calculate power consumption.

FIG. 4 shows battery current data measured in the operation mode and the sleep mode, wherein “original” indicates a current value before ADC conversion, and “ADC value” indicates a current value calculated based on a value converted by the ADC in the MCU.

The battery level processor of the MCU calculates power consumption using the measured current value in the operation mode, and calculates power consumption using the predetermined current value without separate measurement.

At this time, a current value based on the ADC value is used as the current value used to calculate power consumption in the operation mode. That is, power consumption is calculated using an ADC current value for an operation mode time Δta.

Since the current value based on the ADC value is obtained by sampling battery current—which is analogue—in a predetermined sampling cycle and digitally converting the same, a data amount fluctuates depending on the size of the sampling cycle. Consequently, the amount of calculation necessary to calculate power consumption may be reduced by enlarging the sampling cycle (i.e. by reducing a sampling rate per unit time). Power consumption is reduced in proportion to the reduced amount of calculation.

In addition, the predetermined current value in the sleep mode may be a value preset by measuring battery current using a separate measurement instrument when the remote meter-reading terminal unit is in the sleep mode. The predetermined current value may be stored in the memory, and may be read by the MCU so as to be used to calculate power consumption for a sleep mode time Δts at the time of calculation of power consumption in the sleep mode.

The MCU subtracts the calculated power consumption from the battery power to calculate the current battery level.

As is apparent from the above description, technology according to the present invention is capable of effectively measuring a battery level while minimizing additional power consumption for measurement.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

1. A remote meter-reading terminal unit that periodically receives flow-rate information from a metering unit and transmits the flow-rate information to an outside through a communication network, the remote meter-reading terminal unit comprising:
a memory configured to store the flow-rate information;
a communication module configured to perform data transmission to the outside; and
an MCU having an operation mode in which at least one processor is operated and a sleep mode in which all processors are dormant, the MCU comprising a battery level processor configured to calculate a level of the battery, the battery level processor using current output from the battery to obtain power consumption in the operation mode and using a predetermined current value to obtain power consumption in the sleep mode, wherein
the MCU further comprises: a flow-rate reception processor configured to receive the flow-rate information from the metering unit in a first cycle and to store the flow-rate information in the memory; and an outward transmission processor configured to transmit the flow-rate information to the outside in a second cycle greater than the first cycle,
the sleep mode is set to be temporally longer than the operation mode, and
the outward transmission processor is operated during operation of the flow-rate reception processor while the battery level processor is operated during operation of the flow-rate reception processor or the outward transmission processor.

2. The remote meter-reading terminal unit according to claim 1, wherein the current output from the battery is converted by an ADC in the MCU and then used for obtaining the power consumption in the operation mode.

3. The remote meter-reading terminal unit according to claim 1, wherein the predetermined current value comprises a current value stored in the memory.

4. The remote meter-reading terminal unit according to claim 1, wherein
the first cycle is 1 hour while the second cycle is 24 hours, and
the outward transmission processor transmits all flow-rate information received after outward transmission during a previous cycle.

5. The remote meter-reading terminal unit according to claim 1, further comprising:
a current measurement circuit configured to measure the current output from the battery, wherein
the current measurement circuit comprises:
a resistor connected to a positive terminal and a negative terminal of the battery therebetween;
a first current distributer having a positive side connected to a positive side of the resistor and a negative side connected to an input side of the MCU; and
a second current distributer having a negative side connected to a negative side of the resistor and a positive side connected to the negative side of the first current distributer.

6. An ultrasonic meter comprising the remote meter-reading terminal unit according to claim 1.

7. A remote meter-reading system comprising:
an ultrasonic metering unit installed in a flow-rate measurement target pipe;
the remote meter-reading terminal unit according to claim 1; and
a server configured to receive flow-rate information from the remote meter-reading terminal unit through an external communication network.

8. An ultrasonic meter comprising the remote meter-reading terminal unit according to claim 2.

9. An ultrasonic meter comprising the remote meter-reading terminal unit according to claim 3.

10. An ultrasonic meter comprising the remote meter-reading terminal unit according to claim 4.

11. An ultrasonic meter comprising the remote meter-reading terminal unit according to claim 5.

12. A remote meter-reading system comprising:
an ultrasonic metering unit installed in a flow-rate measurement target pipe;
the remote meter-reading terminal unit according to claim 2; and
a server configured to receive flow-rate information from the remote meter-reading terminal unit through an external communication network.

13. A remote meter-reading system comprising:
an ultrasonic metering unit installed in a flow-rate measurement target pipe;
the remote meter-reading terminal unit according to claim 3; and
a server configured to receive flow-rate information from the remote meter-reading terminal unit through an external communication network.

14. A remote meter-reading system comprising:
an ultrasonic metering unit installed in a flow-rate measurement target pipe;
the remote meter-reading terminal unit according to claim 4; and
a server configured to receive flow-rate information from the remote meter-reading terminal unit through an external communication network.

15. A remote meter-reading system comprising:
an ultrasonic metering unit installed in a flow-rate measurement target pipe;
the remote meter-reading terminal unit according to claim 5; and
a server configured to receive flow-rate information from the remote meter-reading terminal unit through an external communication network.
